(19) United States
(12) Patent Application Publication
(10) Pub. No.: US 2014/0318713 A1
(43) Pub. Date: Oct. 30, 2014

(54) INTERCHANGEABLE CUT TAPE / LEADERLESS FEEDER FINGER ADAPTABLE TO VARIOUS SURFACE MOUNT ASSEMBLY MACHINE FEEDERS FOR CHIP MOUNTERS

(71) Applicant: Kelvin Wiley, Solana Beach, CA (US)

(72) Inventor: Kelvin Wiley, Solana Beach, CA (US)

(21) Appl. No.: 14/279,035

(22) Filed: May 15, 2014

Related U.S. Application Data
(60) Provisional application No. 61/786,620, filed on Mar. 15, 2013.

(51) Int. Cl. H05K 13/02; B32B 43/00

(52) U.S. Cl. CPC H05K 13/02; B32B 43/006
USPC 156/701; 156/750; 156/761

(57) ABSTRACT

Provided is a cut tape/leaderless feeder finger for use in tape feeders for component mounters. The cut tape/leaderless feeder finger can be attached to existing component tape feeders to allow feeding of component tape without a leader. The cut tape/leaderless feeder finger includes a stripping mechanism that folds and creases the top cover of component carrier tape to expose the component in the tape. The cover tape stays attached to the carrier tape and is folder and creased out of the way of the feeder mechanism and the chip mounter. The component tape passes between guides that retain the component in the tape until it is picked by the component mounter.

### INCORPORATION BY REFERENCE TO ANY PRIORITY APPLICATIONS

This application claims the benefit of U.S. Provisional Application No. 61/786,620, filed Mar. 15, 2013, which is hereby incorporated by reference in its entirety.

Any and all applications for which a foreign or domestic priority claim is identified in the Application Data Sheet as filed with the present application are hereby incorporated by reference under 37 CFR 1.57.

### FIELD OF THE DISCLOSURE

The present disclosure relates generally to a tape feeder for use in chip mounters.

### BACKGROUND

In a conventional component tape feeding method the tape cover is removed by indexing a take-up reel along with indexing of the component supply tape, where the cover is detached and passed around a fixed guide surface and maintained under tension by the take-up reel.

The majority of existing tape feeders utilize a sprocket having pins on the periphery thereof which are engagable in the indexing holes of the component tape so as to feed the tape by rotation of the sprocket. These prior art tape feeders require the component tape reel be supplied with a foot long leader attached to the end of the component reel for the purpose of starting the feed process. Tape feeders are generally stacked together side-by-side to provide the maximum amount of feeders in a minimum amount of space and generally it is necessary to remove a feeder in order to change the component tape.

### SUMMARY OF THE DISCLOSURE

The present disclosure relates generally to a tape feeder for use in chip mounters. In an embodiment, the tape feeder includes a component tape guide mechanism that delivers the tape to an indexing sprocket where the component is removed for subsequent handling, such as transfer to a conveyor or a circuit board.

In an embodiment, the disclosure is directed to feeders using paper tapes having pockets containing surface mountable electrical components. Typically the top cover of the component tape is peeled away from the substrate so as to open each pocket in turn, and thus provide access to the component therein. Auxiliary covers or movable “shutters” often are provided to prevent loss of components from opened pockets.

Several types of supply tapes are used presently, and the disclosure is applicable to these and other component supply tapes. One tape has a paper substrate embossed to define component holding pockets which are enclosed by a separable thin plastic top cover; another tape has holes all the way through a cardboard substrate with top and bottom covers for the holes so as to define the component pockets.

Current systems that use supply tapes have several drawbacks. For example, loading the feeders is often time consuming and requires disposing of valuable components if a leader is not attached to the tape. Moreover, if a jam or breakage of the tape occurs with standard, current tape feeders, it is generally necessary to remove and replace the entire feeder assembly or to shut it down for an uneconomical length of time necessary to clear the jam or to rethread the tape in the feeder and/or the cover material into the peeler.

In an embodiment, the present disclosure provides a cut tape/leaderless feeder finger for use in component tape feeders that redefines the concept of feeding component tape to a chip mounter, the cut tape/leaderless feeder finger includes a housing body, tape guide, and cover tape separator. In an embodiment, the cut tape/leaderless feeder finger can be mounted on existing component tape feeders of any manufacturer. Alternatively, the cut tape/leaderless feeder can be formed integrally or as part of a new tape feeder system.

In an embodiment, the present disclosure also provides a cut tape/leaderless feeder finger for use on a component tape feeder having a guide structure for stable feeding of component tape to the indexing sprocket. The guide structure includes an opening through which the component can be accesses by the chip mounter.

In an embodiment, the present disclosure also provides a cut tape/leaderless feeder finger for use on a component tape feeder having a guide structure with a fixed cover tape separator utilized to guide the top cover out of the way of the component tape opening while folding and creasing the cover onto the substrate for easy exit from the feeder body. In such an embodiment, the cover is only partially removed from the tape body, such that the cover does not need to be separately collected after use, but rather is collected after use with the rest of the tape body. This significantly simplifies the tape feeder process.

According to an aspect of the present disclosure there is provided a cut tape/leaderless feeder finger used in conjunction with component tape feeders, the cut tape/leaderless feeder finger including: a frame along which the component tape is fed, a fixed cover tape separator, and a guide mechanism that pushes the component tape against the frame and into the exit opening. The empty substrate and folded top cover are guided out of the feeder finger and into the exit tunnel of the component feeder. The empty component tape with its top cover attached is discarded.

### BRIEF DESCRIPTION OF THE DRAWINGS

FIG. 1 is an isometric view of an embodiment of the disclosure.

FIG. 2 is a bottom plan view of the embodiment of FIG. 1.

FIG. 3 is a left side view of the embodiment of FIG. 1.

FIG. 4 is a right side view of the embodiment of FIG. 1.

FIG. 5 is a rear view of the embodiment of FIG. 1,

FIG. 6 is a rear view with tunnel shown in FIG. 1

FIG. 7 is a top view of the embodiment of FIG. 1 illustrating the tape guide and top cover separator portions of the device.

FIG. 8 is a detail view of the cover tape separator of FIG. 1

FIGS. 9 -10 are partial top views illustrating the tape feeding and cover peeling operations

FIG. 11 is an isometric view of the bottom of FIG. 1.

FIG. 12 is a partial isometric view illustrating a component supply tape with pocketed substrate, cover therefore, and component carried thereby.

### DETAILED DESCRIPTION

Although specific embodiments of the present disclosure will now be described with reference to the drawings, it should be understood that such embodiments are by way of example only and merely illustrative of but a small number of the many possible specific embodiments which can represent applications of the principles of the present disclosure. Various changes and modifications obvious to one skilled in the art to which the present disclosure pertains are deemed to be within the spirit, scope and contemplation of the present disclosure as further defined in the claims.

Embodiments of the present disclosure are intended to describe a system that connects to and operates with existing tape feeders systems. For example, in some embodiments, the system described herein operates in conjunction with the tape feeder described in U.S. Pat. Nos. 8,006,373 and 7,448,130, incorporated herein by reference. Of course, it is to be understood that the present disclosure can be used with any new or existing tape feeder systems.

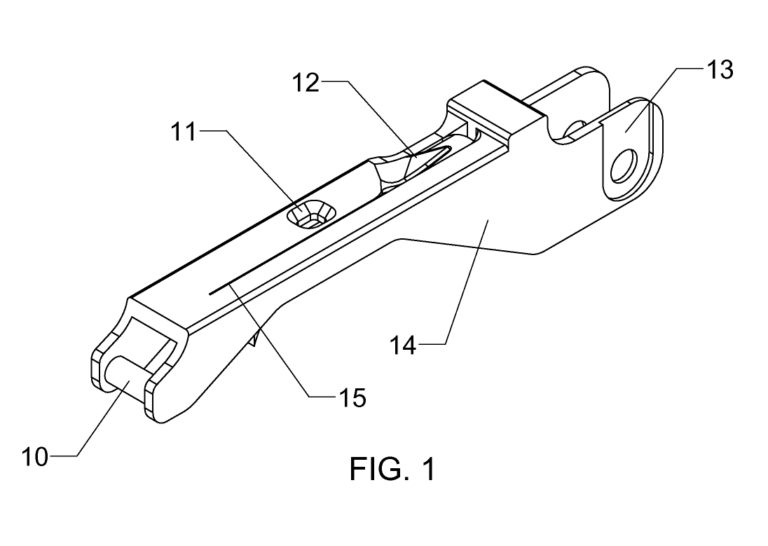

Referring to FIG. 1, illustrated is a perspective view of the present disclosure which includes a cut tape/leaderless feeder finger. The apparatus includes a feeder finger body (14), tape guide (15), and cover tape separator (12), such as, for example, a plow blade. Cover tape separator (12) is used for feeding a conventional carrier tape, for example, as illustrated in FIG. 12, with successive sprocket holes (33) and indexed pockets (31) for carrying small components and used in conjunction with various component feeders for surface-mounting of the small components onto a printed circuit board (PCB).

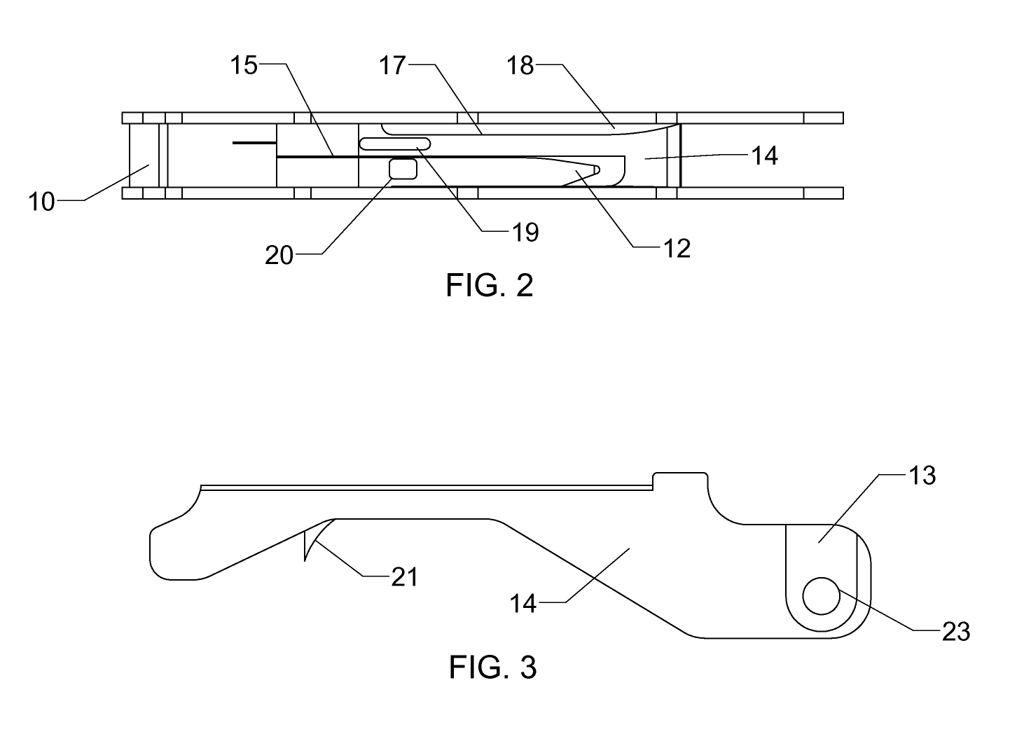

Referring to FIG. 2, illustrated is the bottom plan view of the cut tape/leaderless feeder finger depicting the slot relief (17) for the sprocket that indexes the component carrier tape pass the component opening (20). The cover tape is only partially detached from the component carrier tape by the cover tape separator (12). The component carrier tape and partially detached cover tape are directed by the tape guide (18) and the top support (14). The partially detached cover tape travels through the guide tunnel (15) where it is rolled into a tube and folded onto the opposite side of the component carrier tape. Thus, one side of the cover tape is detached from the component carrier tape and folded over onto the other side of the component carrier tape, exposing the underlying components on the component carrier tape.

Referring to FIG. 3, illustrated is the left side plane view of the cut tape/leaderless feeder finger that includes the exit guide (21) the barrel support (23) and the clamp relief (22). The exit guide provides support for the component carrier tape (and tape cover) as it is directed towards the exit on the component feeder, the barrel support (23) and clamp relief (22) support the cut tape/leaderless feeder finger when it is attached to the component feeder.

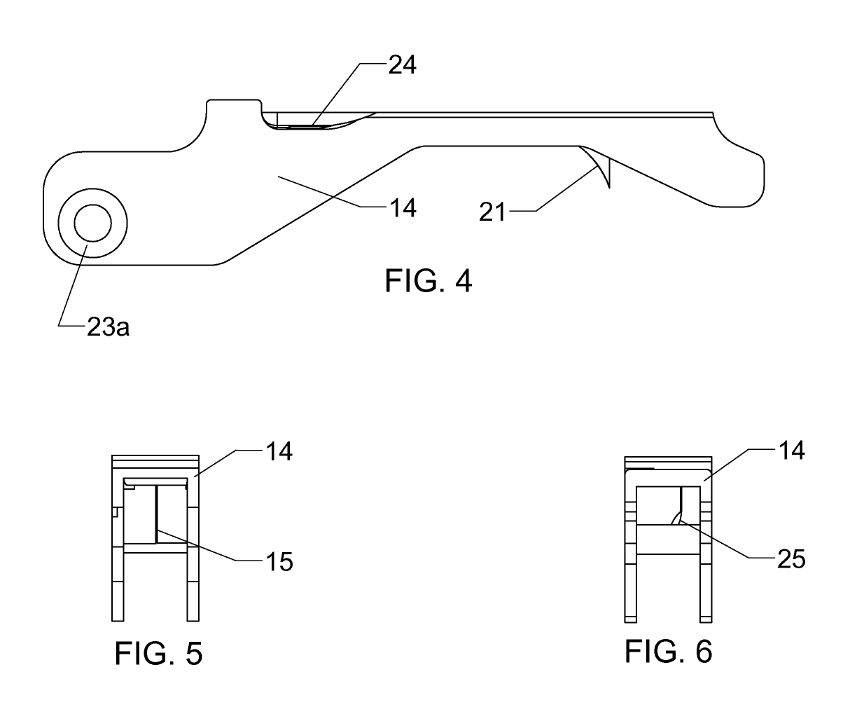

Referring to FIG. 4, illustrated is the right side plane view of the cut tape/leaderless feeder finger with the tape exit guide (21), the barrel head relief (23a) and a side view of the cover tape separator (24) [FIG. 1 (12)]. The cover tape separator (24) provides the key function of partially separating the top cover from the substrate and directing the top cover away from the mechanical features of the component feeder.

Referring to FIG. 5, illustrated is the rear view of the cut tape/leaderless feeder finger with the cover tape guide (15) shown. The cover tape guide is utilized to provide a path through the cut tape/leaderless feeder finger as it is directed towards the exit.

Referring to FIG. 6, illustrated is the front view of the cut tape leaderless feeder finger in this view the tunnel (25) is shown. The function of the tunnel is to fold and crease the cover tape away from the mechanical features of the component feeder as the tape is indexed towards the exit.

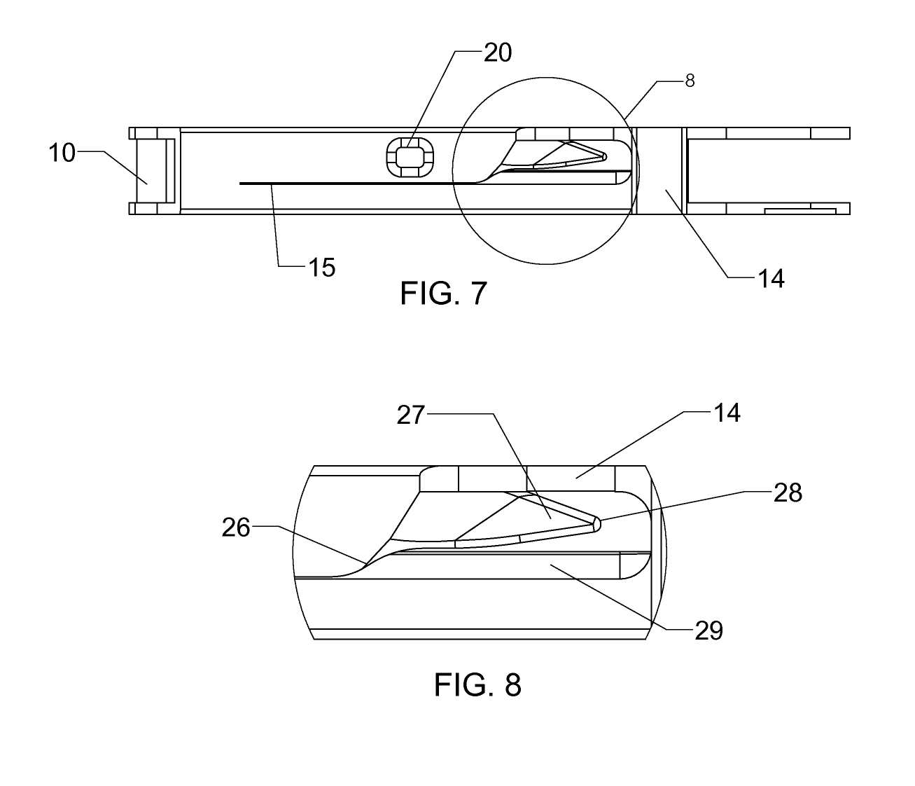

Referring to FIG. 7 and FIG. 8, illustrated is the top view of the device with an enlarged view of the cover tape separator (27) [FIG. 1(12)] and the cover tape top support (29). The function of the top support (29) is to hold the undetached side of the cover tape in place as it travels through the tape guide (14) and into exit tunnel (26).

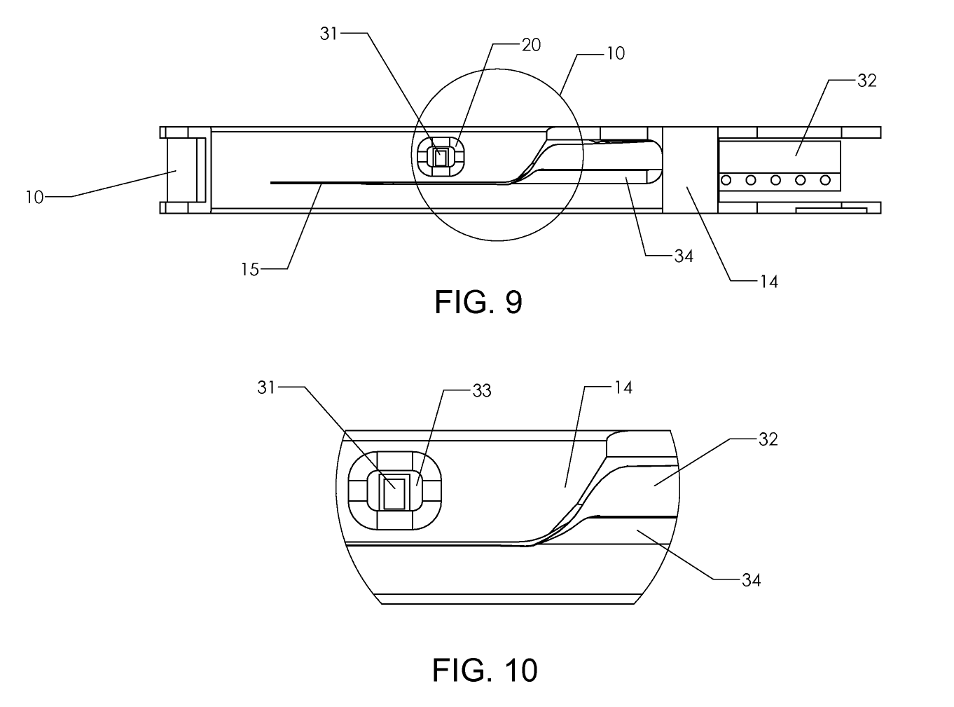

Referring to FIG. 9, and FIG. 10, illustrated is the feed and peel details as described in the function and operation of the cut tape/leaderless feeder finger. The primary function of the present disclosure is to provide efficient access to electrical components incased in component tape. One of the benefits is the ability to feed component tape without a leader attached. This in turn allows the first component on the reel to be picked which eliminates component waste associated with splicing component tape. This is because a portion of the component carrier tape is not lost in the tape setup required for prior art tape feeders. Moreover, no tape leader portion of any kind is required, thus significantly reducing initial feeder setup time. The feeding and peeling as illustrated here provides access to the component as the component tape (33) is pushed through the tape guide (14) and onto the cover tape separator. The undetached side of the cover tape is held in place by the top cover support (34) where the cover support (34) supplies pressure to the top cover as it travels through the cut tape/leaderless feeder finger. When the first component (31) reaches the component opening (20) the sprocket pins engage the component tape (33) and the component tape is indexed thru the cut tape/leaderless feeder finger (14) with each cycle of the component feeder. The process as described reduces feeder setup time and eliminates feeder jams associated with standard, current tape feeders

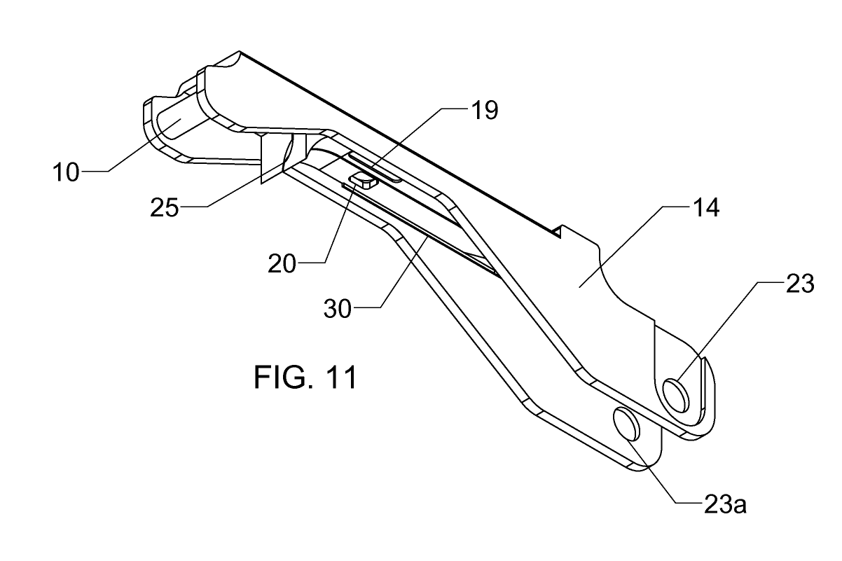

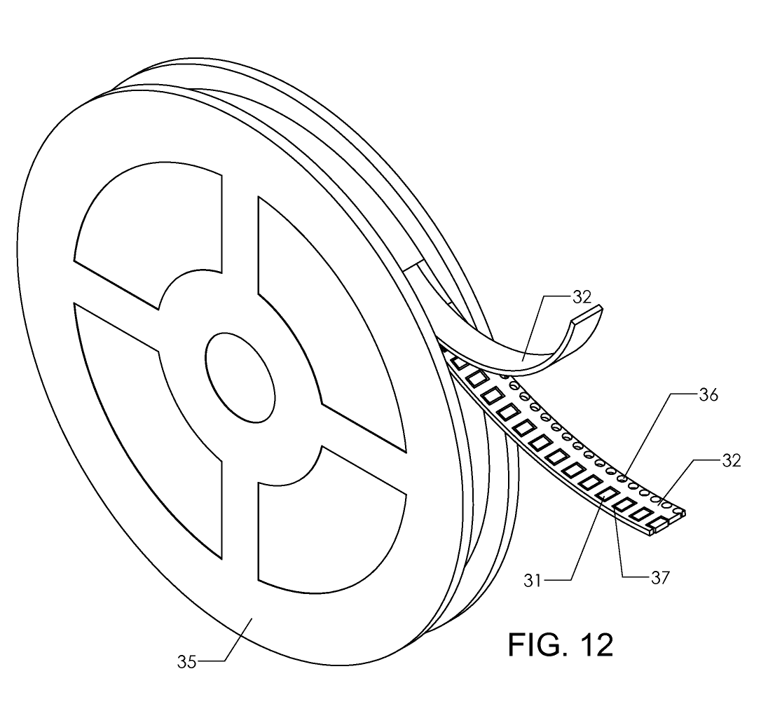

Referring to FIG. 11, illustrated is an isometric bottom view of the cut tape/leaderless feeder finger detailing the cover tape exit tunnel (25). The tunnel acts to keep the top cover away from the mechanical features of the component feeder. After each index of the sprocket the component comes to rest at the component opening (20). The component opening (20) provides access to the component after the cover tape is removed. The sprocket relief (19) provides clearance for the sprocket (not shown) to pass through the tape. The tape guide (30) aligns the tape to engage the sprocket. The cut tape/leaderless feeder finger is attached to the component feeder with a dowel pin, through the pin hole supports (23 and 23a). The front dowel (10) is provided to latch the feeder finger in place.

Referring to FIG. 12, illustrated is a typical reel used to supply products such as integrated circuit (IC) chips. The components in the tape are susceptible to contamination by foreign matters, such as dust, for example. Hence, to be protected from foreign matters and for easy handling the IC chips are separately accommodated in an array of accommodating spaces on a carrier of a tape. The tape comprising carrier (37) and IC chips is wound around a reel (35) to facilitate handling and transport. The accommodating spaces (31) of the carrier (37) are covered with a tape cover (32). A plurality of transfer holes (36) are formed at predetermined intervals on one edge of a carrier for advancing the carrier when the reel (35) is used with a component mounter including a tape feeding unit. Different configurations of component carrier tape can be used and the present disclosure is not to be limited to the type of tape or specific tape feeder embodiments disclosed herein, rather the principals described can be used with any type or configuration of tape feeders and component carrier tape.

Component tape is supplied to the cut tape/leaderless feeder finger without the requirement of a leader. The component tape FIG. 12 is fed into the tape guide and onto the cover tape separator. The top cover (32) is peeled from the component supply tape (37) on one side by passing the top cover (32) over the cover tape separator. The component tape is pushed until it reaches the component opening and engages the sprocket pins. As the component tape is indexed through the cut tape/leaderless feeder finger, the top cover is forced over the top cover separator (12) and into a tunnel (15) where it is rolled into a tube and creased onto the opposite side of the component carrier tape. The component carrier tape is indexed into a guide that directs it towards the exit of the cut tape/leaderless feeder finger FIG. 1 and into the exit tube of the component feeder . The empty component tape exits the component feeder with the top cover attached and folded neatly out of the way of the component pocket and index sprocket.

What is claimed is:

1. A tape feeder comprising:
a first end;
a second end;
a top support extending between the first end and the second end, the top support having a first side and a second side, the first side separated from the second side by a tape guide channel; and
a cover tape separator extending from the first side of the top support toward the first end of the tape feeder, the cover tape separator configured to direct a portion of a top cover of a component tape into the tape guide channel and to direct a carrier portion of the component tape beneath the first side of the top support.

2. The tape feeder of claim 1, wherein the first side of the top support includes a component opening there through, the component opening configured to permit access to and removal of a component from the component tape through the component opening.

3. The tape feeder of claim 1, wherein the tape feeder further comprises an exit guide on a bottom side top support between the cover tape separator and the second end of the tape feeder, the exit guide configured to guide the component tape away from the top support.

4. The tape feeder of claim 3, wherein the exit guide comprises a ramp extending downward from a lower surface of one or more of the first side and the second side of the top support

5. The tape feeder of claim 1, wherein the cover tape separator comprises a plow blade configured to partially separate the top cover of the component tape from the carrier portion of the component tape without completely separating the top cover from the carrier portion.

6. The tape feeder of claim 1, further comprising a dowel at or near the second end of the tape feeder, the dowel configured to facilitate coupling of the tape feeder to a tape feeder system.

7. The tape feeder of claim 1, wherein the tape feeder is configured to feed component tape having a length of approximately 6 inches.

8. A method of separating electronic components from component tape, the method comprising the steps of:
feeding the component tape into a first end of a tape feeder;
directing the component tape to a cover tape separator; and
partially separating a top cover of the component tape from a carrier portion of the component tape such that a portion of the top cover remains connected to the carrier portion as the component tape passes the cover tape separator.

9. The method of claim 8, further comprising directing the partially separated top cover into a tape guide channel of the tape feeder.

10. The method of claim 8, further comprising directing the partially separated top cover and carrier portion away from the tape feeder.

11. The method of claim 8, further comprising removing an electronic component from the carrier portion through a component opening of the tape feeder.

12. The method of claim 8 further comprising attaching the tape feeder to a tape feeder system.

13. A tape feeder system comprising:
a feeder mechanism configured to feed a component tape; and
a tape feeder having:
a first end;
a second end;
a tape guide channel; and
a cover tape separator extending toward the first end of the tape feeder, the cover tape separator configured to direct a portion of a top cover of a component tape into the tape guide channel.

14. The tape feeder system of claim 13, further comprising a chip mounter configured to remove electronic components from the carrier portion of the component tape.

15. The tape feeder system of claim 13, wherein the tape feeder further comprises a component opening through which electronic components may be removed from the carrier portion of the component tape.

16. The tape feeder system of claim 13, wherein the tape feeder comprises a connection structure configured to facilitate coupling of the tape feeder to the tape feeder system.

17. The tape feeder system of claim 16, wherein the connection structure is a dowel.

18. The tape feeder system of claim 13, wherein the cover tape separator comprises a plow blade.

19. The tape feeder system of claim 13, further comprising an exit guide configured to direct the component tape away from the tape feeder after the component tape passes the cover tape separator.

20. The tape feeder system of claim 19, wherein the exit guide comprises a ramp.

21. A stripping mechanism for manipulating a top cover of a component carrier tape to expose a component in the tape while leaving the top cover attached and out of the way of a feeder mechanism and component mounter comprising:
a housing; and
a tape separator configured to partially separate the component carrier tape from the top cover strip.

22. The stripping mechanism of claim 21, wherein the stripping mechanism attaches to existing tape feeders of any component feeder manufacture.

23. The stripping mechanism of claim 21, wherein the stripping mechanism requires no leader when loading the tape into a component feeder.

24. The stripping mechanism of claim 21, wherein the stripping mechanism is able to feed short segments of component carrier tape without splicing.

25. The stripping mechanism of claim 21, wherein the feeder feeds cut component tape as short as six inches.

26. The stripping mechanism claim 21, wherein stripping mechanism is interchangeably used in conjunction with component tape feeders of various feeder manufactures.
